(19) United States
(12) Patent Application Publication
(10) Pub. No.: US 2025/0107119 A1
(43) Pub. Date: Mar. 27, 2025

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Yuichi HASHIZUME, Matsumoto-city (JP); Shin MIYAMOTO, Matsumoto-city (JP)

(73) Assignee: FUJI ELECTRIC CO., LTD., Kawasaki-shi (JP)

(21) Appl. No.: 18/820,920

(22) Filed: Aug. 30, 2024

(30) Foreign Application Priority Data
Sep. 27, 2023 (JP) 2023-166545
Jun. 6, 2024 (JP) 2024-092633

(51) Int. Cl. H01L 29/872; H01L 27/02; H01L 29/06; H01L 29/16; H01L 29/45; H01L 29/66

(52) U.S. Cl. CPC H10D 8/60; H10D 8/051; H10D 62/124; H10D 62/83; H10D 64/62; H10D 89/10; H10D 62/8325

(57) ABSTRACT

A semiconductor device includes an active region, a first-conductivity-type region, and a termination region. The active region has first second-conductivity-type regions, silicide films, and a first electrode; the termination region has a second second-conductivity-type region. The active region is configured by ohmic regions where the first electrode is in contact with the silicide films, and Schottky regions where the first electrode is in contact with the first-conductivity-type region. When a doping concentration of the first-conductivity-type region is a low concentration, a greater number of the ohmic regions is provided in a chip center portion than in a chip outer peripheral portion and when the doping concentration of the first-conductivity-type region is a high concentration, a greater number of the ohmic regions is provided in the chip outer peripheral portion than in the chip center portion.

### CROSS REFERENCE TO RELATED APPLICATIONS

This application is based upon and claims the benefit of priority of the prior Japanese Patent Application No. 2023-166545, filed on Sep. 27, 2023, and Japanese Patent Application No. 2024-92633, filed on Jun. 6, 2024, the entire contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Conventionally, a semiconductor device has been proposed in which regions forming Schottky junctions and regions forming ohmic junctions are provided in an electrode, whereby thermal destruction resistance is enhanced in instances in which large current such as surge current flows in a forward direction (for example, refer to Japanese Laid-Open Patent Publication No. 2021-93522 and Japanese Laid-Open Patent Publication No. 2014-78660).

### SUMMARY OF THE INVENTION

According to an embodiment of the present disclosure, a semiconductor device includes: a semiconductor substrate having an active region and a termination region surrounding a periphery of the active region, the semiconductor substrate having a first main surface and a second main surface opposite to each other; a first-conductivity-type region provided in the semiconductor substrate and exposed at the first main surface of the semiconductor substrate; a plurality of second-conductivity-type regions each selectively provided in the first-conductivity-type region, at the first main surface of the semiconductor substrate in the active region; and a plurality of silicide films each in ohmic contact with a portion of a corresponding one of the plurality of second-conductivity-type regions. The active region has a chip center portion provided at a center thereof, and a chip outer peripheral portion surrounding a periphery of the chip center portion. In a case where the first-conductivity-type region is in a low concentration condition in which a doping concentration of the first-conductivity-type region is 1.0×10¹⁵/cm³ or more but less than 1.0×10¹⁶/cm³, a total area or a total number of the plurality of silicide films provided in the chip center portion is greater than is a total area or a total number of the plurality of silicide films provided in the chip outer peripheral portion. In a case where the first-conductivity-type region is in a high concentration condition in which the doping concentration of the first-conductivity-type region is in a range of 1.0×10¹⁶/cm³ to 9.0×10¹⁶/cm³, the total area or the total number of the plurality of silicide films provided in the chip center portion is less than is the total area or the total number of the plurality of silicide films provided in the chip outer peripheral portion.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure in an instance in which a silicon carbide semiconductor device according to a first embodiment has a drift layer with a high concentration.

FIG. 2A is a plan view depicting a layout when the silicon carbide semiconductor device is viewed from a front side of a semiconductor substrate thereof.

FIG. 2B is a plan view depicting another layout when the silicon carbide semiconductor device is viewed from the front side of the semiconductor substrate thereof.

FIG. 3 is a cross-sectional view depicting the structure in an instance in which the drift layer of the silicon carbide semiconductor device according to the first embodiment has a low doping concentration.

FIG. 4A is a plan view depicting a layout when the silicon carbide semiconductor device according to the first embodiment depicted in FIG. 3 is viewed from the front side of the semiconductor substrate thereof.

FIG. 4B is a plan view depicting another layout when the silicon carbide semiconductor device according to the first embodiment depicted in FIG. 3 is viewed from the front side of the semiconductor substrate thereof.

FIG. 5 is a cross-sectional view depicting, in detail, the structure of a region S surrounded by a dashed line in FIG. 3.

FIG. 6 is a plan view depicting a chip outer peripheral portion and a chip center portion when the silicon carbide semiconductor device according to the first embodiment is viewed from the front side of the semiconductor substrate.

FIG. 7 is a cross-sectional view depicting the structure in an instance in which the drift layer of the silicon carbide semiconductor device according to a second embodiment has a low concentration.

FIG. 8A is a plan view of a layout when the silicon carbide semiconductor device according to the second embodiment in FIG. 7 is viewed from the front side of the semiconductor substrate.

FIG. 8B is a plan view of another layout when the silicon carbide semiconductor device according to the second embodiment in FIG. 7 is viewed from the front side of the semiconductor substrate.

FIG. 9 is a cross-sectional view depicting the structure in an instance in which the drift layer of the silicon carbide semiconductor device according to the second embodiment has a high concentration.

FIG. 10A is a plan view of a layout when the silicon carbide semiconductor device according to the second embodiment in FIG. 9 is viewed from the front side of the semiconductor substrate.

FIG. 10B is a plan view of another layout when the silicon carbide semiconductor device according to the second embodiment in FIG. 9 is viewed from the front side of the semiconductor substrate.

FIG. 11 is a cross-sectional view depicting a conventional structure of the silicon carbide semiconductor device.

FIG. 12 is a plan view of a layout when the conventional silicon carbide semiconductor device is viewed from a front side of the semiconductor substrate.

### DETAILED DESCRIPTION OF THE INVENTION

First, problems associated with the conventional techniques are discussed. When surge current flows in a p⁺-type region, bipolar operation of the p⁺-type region is delayed due to contact resistance of the p⁺-type region, a semiconductor device element generates heat and may be destroyed.

An overview of an embodiment of the present disclosure is described. A semiconductor device according to the present disclosure has the following features. The semiconductor device includes a semiconductor substrate having an active region and a termination region surrounding a periphery of the active region, the semiconductor substrate having a first main surface and a second main surface opposite to each other; a first-conductivity-type region provided in the semiconductor substrate and exposed at the first main surface of the semiconductor substrate; a plurality of second-conductivity-type regions each selectively provided in the first-conductivity-type region, at the first main surface of the semiconductor substrate in the active region; a plurality of silicide films each in ohmic contact with a portion of a corresponding one of the plurality of second-conductivity-type regions; a first electrode in contact with the plurality of silicide films, the plurality of first second-conductivity-type regions, and the first-conductivity-type region; a second electrode provided at the second main surface of the semiconductor substrate; and a second second-conductivity-type region provided in the termination region and surrounding the active region. The active region is configured by plurality of ohmic regions where the first electrode is in contact with the plurality of silicide films, and a plurality of Schottky regions where the first electrode is in contact with the first-conductivity-type region. In the termination region, the second second-conductivity-type region is in contact with a corresponding one of the plurality of ohmic regions. When a doping concentration of the first-conductivity-type region is a low concentration of 1.0×10¹⁵/cm³ or greater but less than 1.0×10¹⁶/cm³, an area or a number of the plurality of ohmic regions provided in a chip center portion is greater than an area or a number of the plurality of ohmic regions provided in a chip outer peripheral portion, the doping concentration of the first-conductivity-type region is a high concentration in a range of 1.0×10¹⁶/cm³ to 9.0×10¹⁶/cm³, the area or the number of the plurality of ohmic regions provided in the chip outer peripheral portion is greater than the area or the number of the plurality of ohmic regions provided in the chip center portion.

According to the disclosure above, when a doping concentration of an n-type drift region (first-conductivity-type region) is a low concentration, surge current concentrates in the outer periphery of the chip and thus, a greater area or number of the plurality of ohmic regions is provided in the chip center portion, whereby destruction in the outer periphery of the chip may be prevented. Further, when the doping concentration of the n-type drift region is a high concentration, surge current concentrates directly beneath wiring or in the chip center and thus, a greater area or number of the plurality of ohmic regions is provided in the chip outer peripheral portion, whereby destruction in the chip center may be prevented.

Further, in the semiconductor device according to the present disclosure, in the disclosure above, the chip center portion is a region provided in a center of the semiconductor device and is a region spanning from a center of each edge of the semiconductor device, to ¼ to ¾ to an end of said each edge, while the chip outer peripheral portion is a region provided in an outer periphery of the semiconductor device and is a region outside a range of ¼ to ¾ from the center of said each edge of the semiconductor device.

Further, in the semiconductor device according to the present disclosure, in the disclosure above, when the doping concentration of the first-conductivity-type region is a low concentration, a plurality of high-resistance junction regions where the first electrode is in contact with the plurality of first second-conductivity-type regions is provided in the chip center portion of the active region; a width of each of the plurality of first second-conductivity-type regions is wider than a width of each of the plurality of silicide films; and a width of one side (one half) of a difference of the width one of the plurality of first second-conductivity-type regions and the width of one of the plurality of silicide films is in a range of 0.1 μm to 5.0 μm.

According to the disclosure above, a width of a first nickel silicide film (the silicide films) is less than a width of each of the p⁺-type regions (first second-conductivity-type regions) and thus, the p⁺-type regions are exposed at the front surface of the semiconductor substrate and the p⁺-type region and the titanium film form high-resistance Schottky junctions.

Further, in the semiconductor device according to the present disclosure, in the disclosure above, when the doping concentration of the first-conductivity-type region is a low concentration, a plurality of high-resistance junction regions where the first electrode is in contact with the plurality of first second-conductivity-type regions is provided the chip center portion of the active region, and in the chip outer peripheral portion, a rate of the area of the plurality of high-resistance junction regions with respect to the area of the plurality of first second-conductivity-type regions is 35% or more.

Further, in the semiconductor device according to the present disclosure, in the disclosure above, when the doping concentration of the first-conductivity-type region is a low concentration, in the chip center portion of the active region, the plurality of high-resistance junction regions where the first electrode is in contact with the plurality of first second-conductivity-type regions are provided, and in the chip center portion, a rate of the area of the plurality of high-resistance junction regions with respect to the area of the active region is in a range of 15% to 40%.

According to the disclosure above, rates of the areas are within these ranges and thus, both enhancement of surge current tolerance and low Vf characteristics may be achieved.

Further, in the semiconductor device according to the present disclosure, in the disclosure above, when the doping concentration of the first-conductivity-type region is a high concentration, in the chip outer peripheral portion of the active region, the plurality of high-resistance junction regions where the first electrode is in contact with the plurality of first second-conductivity-type regions is provided; the width of each of the plurality of first second-conductivity-type regions is wider than the width of each of the plurality of silicide films; and the width of one side (one half) of a difference of the width of one of the plurality of first second-conductivity-type regions and the width of one of the plurality of silicide films is in a range of 0.1 μm to 5.0 μm.

According to the disclosure above, the width of the first nickel silicide film (the plurality of silicide films) is less than the width of the p⁺-type regions (the plurality of first second-conductivity-type regions) and thus, the p⁺-type regions are exposed at the front surface of the semiconductor substrate and the p⁺-type regions and the titanium film form the high-resistance Schottky junctions.

Further, in the semiconductor device according to the present disclosure, in the disclosure above, when the doping concentration of the first-conductivity-type region is a high concentration, in the chip outer peripheral portion of the active region, the plurality of high-resistance junction regions where the first electrode is in contact with the plurality of first second-conductivity-type regions is provided; and in the chip outer peripheral portion, a rate of the area of the plurality of high-resistance junction regions with respect to the area of the plurality of first second-conductivity-type regions is 35% or more.

Further, in the semiconductor device according to the present disclosure, in the disclosure above, when the doping concentration of the first-conductivity-type region is a high concentration, in the chip outer peripheral portion of the active region, the plurality of high-resistance junction regions where the first electrode is in contact with the plurality of first second-conductivity-type regions is provided, and in the chip outer peripheral portion, a rate of the area of the plurality of high-resistance junction regions with respect to the area of the active region is in a range of 15% to 40%.

According to the disclosure above, the rates of the areas are in the ranges above and thus, both enhanced surge current tolerance and low Vf characteristics may be achieved.

Further, in the semiconductor device according to the present disclosure, in the disclosure above, the plurality of silicide films contain nickel, silicon, and aluminum.

A semiconductor device according to the present disclosure has the following features. The semiconductor device has a semiconductor substrate having an active region and a termination region surrounding a periphery of the active region, the semiconductor substrate having a first main surface and a second main surface opposite to each other; a first-conductivity-type region provided in the semiconductor substrate and exposed at the first main surface of the semiconductor substrate; a plurality of second-conductivity-type regions each selectively provided in the first-conductivity-type region, at the first main surface of the semiconductor substrate in the active region; and a plurality of silicide films each in ohmic contact with a portion of a corresponding one of the plurality of second-conductivity-type regions. When a doping concentration of the first-conductivity-type region is a low concentration of 1.0×10¹⁵/cm³ or greater but less than 1.0×10¹⁶/cm³, ones of the plurality of silicide films provided in a termination region side of the active region have a first contact resistance in a range of 5×10⁻⁴ Ω)/cm² to 5×10⁻³ Ω/cm² while other ones of the plurality of silicide films provided toward a center of the active region have a second contact resistance of 5×10⁻⁵ Ω/cm² or more but less than 5×10⁻⁴ Ω/cm² and when the doping concentration of the first-conductivity-type region is a high concentration in a range of 1.0×10¹⁶/cm³ to 9.0×10¹⁶/cm³, ones of the plurality of silicide films provided in the termination region side of the active region have a contact resistance of 5×10⁻⁵ Ω/cm² or more but less than 5×10⁻⁴ Ω/cm² while other ones of the plurality of silicide films provided toward the center of the active region have a second contact resistance in a range of 5×10⁻⁴ Ω/cm² to 5×10⁻³ Ω/cm².

A method of manufacturing a semiconductor device according to the disclosure has the following features. The method of manufacturing is for a semiconductor device having a semiconductor substrate having an active region and a termination region surrounding a periphery of the active region. First, a first process of forming a first-conductivity-type region in the semiconductor substrate is performed, the first-conductivity-type region constituting a first main surface of the semiconductor substrate. Next, a second process of selectively forming, in the active region, between the first main surface of the semiconductor substrate and the first-conductivity-type region, a plurality of first second-conductivity-type regions in contact with the first-conductivity-type region is performed. Next, a third process of forming, in the termination region, a second second-conductivity-type region surrounding the active region is performed. Next, a fourth process of forming an oxide film at the first main surface of the semiconductor substrate is performed, the oxide film covering the first-conductivity-type region and the plurality of first second-conductivity-type regions. Next, a fifth process of selectively removing the oxide film and thereby forming, in the oxide film, a plurality of first openings exposing the plurality of first second-conductivity-type regions is performed. Next, a sixth process of forming a metal material film in the plurality of first openings of the oxide film is performed, the metal material film being in contact with the first main surface of the semiconductor substrate and having a nickel film, an aluminum film, and a metal film with a melting point higher than a melting point of aluminum sequentially stacked. Next, a seventh process of performing a first heat treatment for causing the metal material film and the semiconductor substrate to react, thereby generating a compound layer on the first main surface of the semiconductor substrate, in the plurality of first openings of the oxide film, the compound being self-aligned using the oxide film as a mask is performed. Next, an eighth process of removing an excess portion of the metal material film is performed after the performing the first heat treatment, the excess portion excluding the compound layer. Next, a nineth process of performing a second heat treatment at a temperature higher than a temperature of the first heat treatment is performed, thereby generating a nickel silicide in the compound layer and forming a plurality of silicide films in ohmic contact with the semiconductor substrate, the second heat treatment being performed after the removing the excess portion of the metal material film. Next, after forming the plurality of silicide films, a tenth process of removing portions of the oxide film between the plurality of silicide films, thereby connecting the plurality of first openings and forming a contact hole is performed. Next, an eleventh process of sequentially stacking, on the first main surface of the semiconductor substrate, in the contact hole, a titanium film that is in contact with the first-conductivity-type region and forms a plurality of Schottky junctions with the first-conductivity-type region, and a metal electrode film that contains aluminum is performed, thereby forming a first electrode. Next, a twelfth process of forming a second electrode at a second main surface of the semiconductor substrate is performed.

In the seventh process, when the doping concentration of the first-conductivity-type region is a low concentration of 1.0×10¹⁵/cm³ or more but less than 1.0×10¹⁶/cm³, the temperature of the first heat treatment is set to be 800 degrees C. or higher but less than 1000 degrees C., thereby forming the plurality of silicide films in a termination region side of the active region to have a first contact resistance in a range of 5×10⁻⁴ Ω/cm² to 5×10⁻³ Ω/cm² and the temperature of the first heat treatment is set to be in a range of 1000 degrees C. to 1200 degrees C., thereby forming the plurality of silicide films toward a center of the active region to have a second contact resistance of 5×10⁻⁵ Ω/cm² or more but less than 5×10⁻⁴ Ω/cm², and when the doping concentration of the first-conductivity-type region is a high concentration in range of 1.0×10¹⁶/cm³ to 9.0×10¹⁶/cm³, the temperature of the first heat treatment is set to be in the range of 1000 degrees C. to 1200 degrees C., thereby forming the plurality of silicide films in the termination region side of the active region to have the first contact resistance of 5×10⁻⁵ Ω/cm² or more but less than 5×10⁻⁴ Ω/cm² and the temperature of the first heat treatment is set to be in a range of 800 degrees C. to 1000 degrees C., thereby forming the plurality of silicide films toward the center of the active region to have the second contact resistance in the range of 5×10⁻⁴ Ω/cm² to 5×10⁻³ Ω/cm².

According to the disclosure above, when the doping concentration of the n-type drift region is a low concentration, surge current concentrates in the outer periphery of the chip and thus, the nickel silicide film constituting the plurality of low-resistance ohmic regions is provided in the chip center portion, whereby destruction in the outer periphery of the chip may be prevented. Further, when the doping concentration of the n′-type drift region is a high concentration, surge current concentrates directly beneath wiring or in a chip center and thus, the nickel silicide film constituting the plurality of low-resistance ohmic regions is provided in the chip outer peripheral portion, whereby destruction in the chip center may be prevented.

Findings underlying the present disclosure are discussed. First, problems associated with the conventional semiconductor device are discussed. Silicon carbide (SiC) has been attracting attention as a semiconductor material that can be used for fabricating (manufacturing) semiconductor devices (hereinafter, silicon carbide semiconductor devices) that exceed the limits of a semiconductor device containing a silicon (Si) semiconductor. In particular, as compared to silicon semiconductors, silicon carbide semiconductors have a large critical electrical field strength and high thermal conductivity, and application to high-voltage semiconductor devices (for example, 1200 V or greater) is expected to take advantage of these characteristics.

In an instance in which a silicon carbide semiconductor device is a diode (hereinafter, silicon carbide diode), design specifications for an n-type epitaxial layer constituting an n-type drift region may be set for a thin thickness and a high doping concentration thereof and thus, silicon carbide diodes of a class with a breakdown voltage of about 3300 V generally have a Schottky barrier diode (SBD) structure.

Normally, in an SBD structure, electric field strength at junction surfaces between a semiconductor substrate and a front electrode is high and when reverse voltage is applied, a problem arises in that reverse leakage current increases due to electrons tunneling through a Schottky barrier or due to a surface defect inherent to silicon carbide. Thus, a silicon carbide diode has been proposed that adopts a junction barrier Schottky (JBS) structure in which Schottky junctions and pn junctions are both present in a front side of a semiconductor substrate.

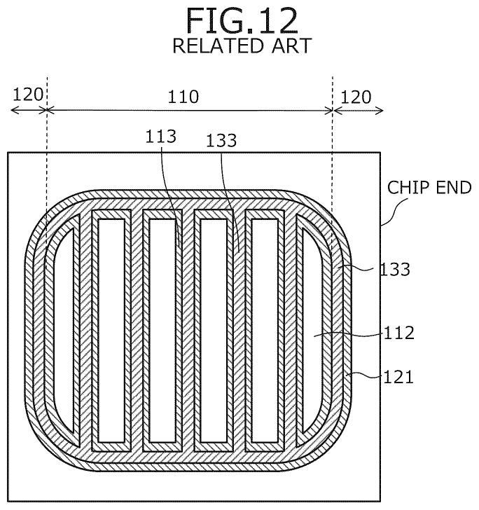

A structure of a conventional silicon carbide diode with an SBD structure is described taking, as an example, a structure of a silicon carbide diode that adopts a JBS structure. FIG. 11 is a cross-sectional view depicting the structure of the conventional silicon carbide semiconductor device.

A conventional silicon carbide semiconductor device 140 depicted in FIG. 11 is a vertical silicon carbide diode having a JBS structure in which, in an active region 110, both an SBD structure constituted by Schottky junctions between an n⁻-type drift region 112 and a titanium film 131 constituting a front electrode 114, and pn junctions between p⁺-type regions 113 and the n-type drift region 112 are present in a semiconductor substrate 130, at a front surface of the semiconductor substrate 130. Further, as a lowest layer of the front electrode 114, a nickel silicide film 133 is provided on each of the p⁺-type regions 113.

The Schottky junctions of the conventional silicon carbide semiconductor device 140 are formed by the n-type drift region 112 exposed at the front surface of the semiconductor substrate 130, and the front electrode 114 configured by an aluminum alloy film 132 and the titanium film 131 provided on the front surface of the semiconductor substrate 130. The semiconductor substrate 130 is an epitaxial substrate in which the n-type epitaxial layer constituting the n-type drift region 112 is stacked on a front surface of an n⁺-type starting substrate 111 containing silicon carbide. The n⁺-type starting substrate 111 constitutes an n⁺-type cathode region. A back electrode 119 is provided in an entire are of back surface of the semiconductor substrate 130 and is electrically connected to the n⁺-type starting substrate 111. Reference numerals 115, 120, 121, and 122 are a field oxide film, an edge termination region, a field limiting ring (FLR), and a p-type region constituting a JTE structure, respectively.

In the semiconductor substrate 130, at the front surface thereof, the p⁺-type regions 113 are selectively provided the active region 110. Between the p⁺-type regions 113 that are adjacent to one another, the n-type drift region 112 is exposed at the front surface of the semiconductor substrate 130. The p⁺-type regions 113 and the n-type drift region 112 form the pn junctions at the front surface of the semiconductor substrate 130. Portions of the n′-type drift region 112 between the p⁺-type regions 113 that are adjacent to one another, form the Schottky junctions with the titanium film 131, which is the lowest layer of the front electrode 114 provided on the front surface of the semiconductor substrate 130.

FIG. 12 is a plan view of a layout when the conventional silicon carbide semiconductor device is viewed from a front side of the semiconductor substrate. As depicted in FIG. 12, in the active region 110, the p⁺-type regions 113 and the nickel silicide film 133 are each provided having a stripe-shape, at ends of which, the p⁺-type regions 113 are connected to the FLR 121 and portions of the nickel silicide film 133 in the active region 110 are connected to a portion of the nickel silicide film 133 on the FLR 121.

With the configuration as described, when a rated current flows in a forward direction, current flows through Schottky regions of the n-type drift region 112 other than the p⁺-type regions 113. Further, when surge current flows due to lightening or the like, the Schottky regions alone are incapable of passing the current and thus, the p⁺-type regions 113 operate bipolarly, whereby current begins to flow. Further, the nickel silicide film 133 constituting ohmic regions is provided on the p⁺-type regions 113, whereby bipolar operation by a stripe structure of only the p⁺-type regions 113 facilitated.

However, when surface current flows through the p⁺-type regions 113, bipolar operation of the p⁺-type regions 113 is delayed due to contact resistance of the p⁺-type regions 113, a semiconductor device element may generate heat and be destroyed. Furthermore, in an instance in which the p⁺-type regions 113 are provided separately from the normal strip stripe structure of the p⁺-type regions 113, an area of the Schottky regions in the n-type drift region 112 decreases, forward voltage Vf during the rated current increases, and the on-voltage increases. As described, when the area of the p⁺-type regions 113 is increased to ensure surge current tolerance (IFSM), a tradeoff occurs in that Vf increases. Furthermore, in a structure in which ohmic regions on a semiconductor device element have a dot structure or the like and each are independent, a problem arises in that resistance is biased, whereby local heat generation easily occurs and surge current tolerance is difficult to ensure.

Furthermore, in the structure in which ohmic regions on the device are independent (such as a dot structure), resistance is biased, local heat generation easily occurs and surge current tolerance is difficult to ensure. In particular, the doping concentration of the ohmic regions differs depending on a doping concentration of the n-type drift region 112 and thus, the location where destruction occurs may change and the surge current tolerance may decrease.

For example, the p⁺-type regions 113 are formed by ion-implantation of a p-type dopant in the n-type drift region 112 and thus, in an instance in which the doping concentration of the n′-type drift region 112 is low, a problem arises in that the doping concentration of the p⁺-type regions 113 increases, surge current concentrates in an outer peripheral portion of a chip (chip outer peripheral portion), and destruction may occur in the chip outer peripheral portion. On the other hand, in an instance in which the doping concentration of the n-type drift region 112 is high, a problem arises in that the doping concentration of the p⁺-type regions 113 decreases, surge current concentrates directly beneath wiring or in a center portion of the chip (chip center portion), and destruction may occur in the chip center portion. Here, the “chip” is the individual conventional silicon carbide semiconductor device 140 into which the semiconductor substrate is diced (cut).

Embodiments of a semiconductor device and a method of manufacturing a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described. Further, in the present description, when Miller indices are described, “-” means a bar added to an index immediately after the “-”, and a negative index is expressed by prefixing “-” to the index. Further, with consideration of variation in manufacturing, description indicating the same or equal may be within 5%.

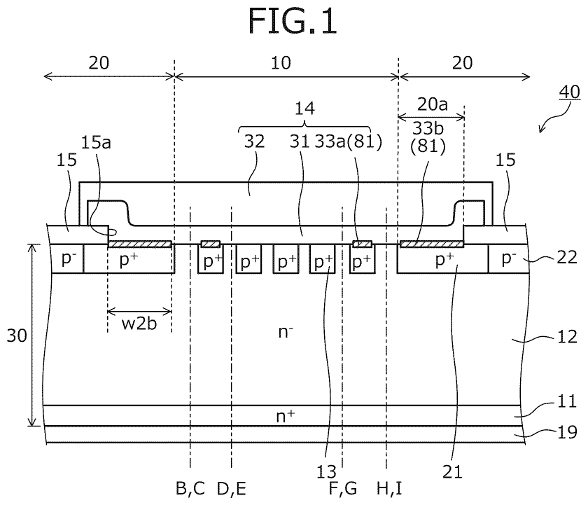

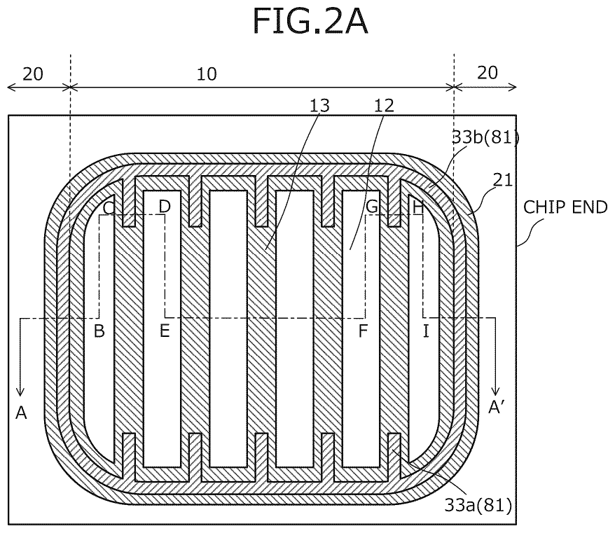

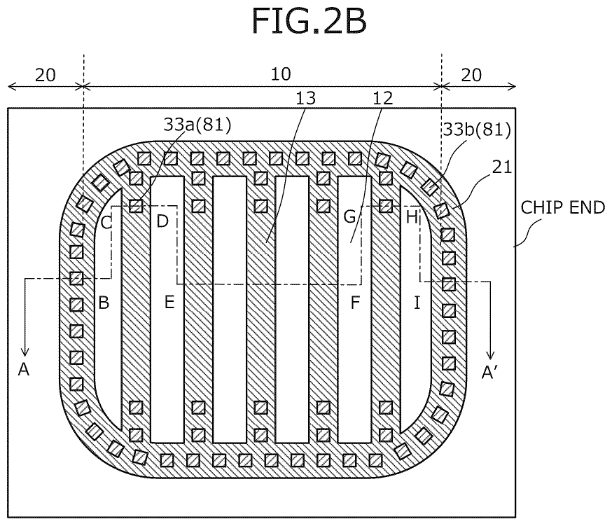

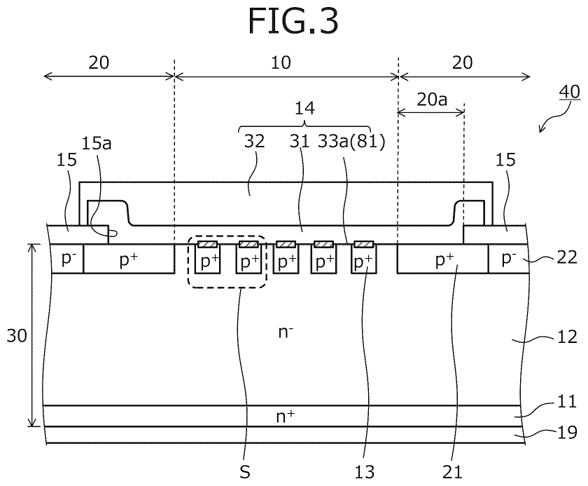

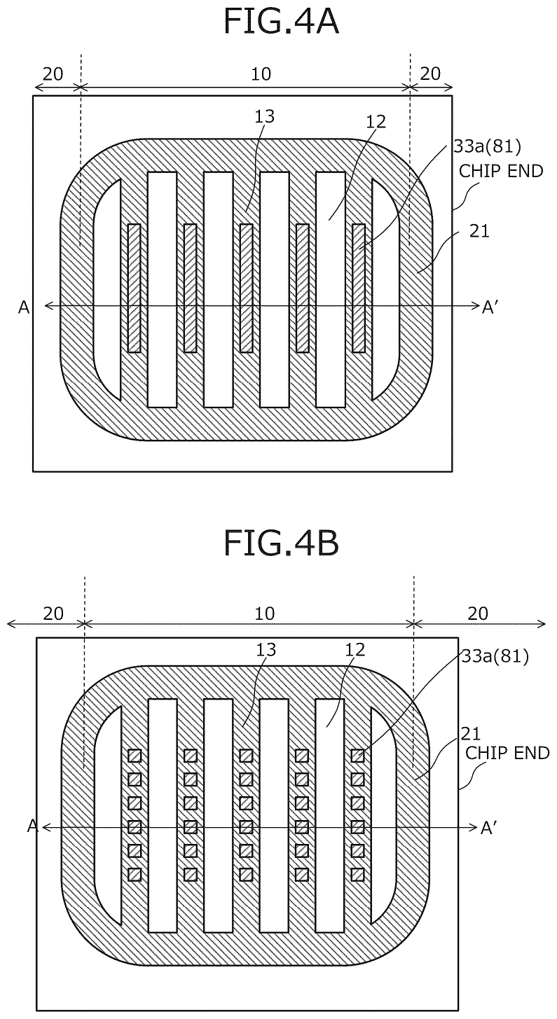

A semiconductor device according to a first embodiment solving the problems above is described. A structure of a silicon carbide semiconductor device is described as the semiconductor device according to the first embodiment. FIG. 1 is a cross-sectional view depicting the structure in an instance in which the silicon carbide semiconductor device according to the first embodiment has a drift layer with a high concentration. FIGS. 2A and 2B are plan views depicting, respectively, examples of layouts of p⁺-type regions (first second-conductivity-type regions) 13 configuring the JBS structure, a field limiting ring ((FLR) second second-conductivity-type region) 21, and nickel silicide films 33. A cross-section of the silicon carbide semiconductor device depicted in FIG. 1 corresponds to a cross-section along cutting line A-A′ in FIGS. 2A and 2B. Cross-sections along cutting line B-C, cutting line D-E, cutting line F-G, and cutting line H-I in the plan views are not depicted in the cross-section along cutting line A-A′ in FIG. 1. FIG. 3 is a cross-sectional view depicting the structure in an instance in which the drift layer of the silicon carbide semiconductor device according to the first embodiment has a low doping concentration. FIGS. 4A and 4B are plan views depicting, respectively, layouts when the silicon carbide semiconductor device according to the first embodiment depicted in FIG. 3 is viewed from a front side of a semiconductor substrate thereof. FIGS. 4A and 4B depict, respectively, examples of layouts of the p⁺-type regions (first second-conductivity-type regions) 13 configuring the JBS structure, the field limiting ring (second second-conductivity-type region) 21, and the nickel silicide films 33. Here, FIG. 3 is a cross-sectional view along cutting line A-A′ in FIGS. 4A and 4B. FIGS. 2A and 4A are examples in which the area of the nickel silicide films (ohmic regions) is changed while FIGS. 2B and 4B are examples in which the number of the nickel silicide films (ohmic regions) is changed.

A the silicon carbide semiconductor device 40 according to the first embodiment depicted in FIGS. 1 to 4B is a silicon carbide diode having a JBS structure in which in a semiconductor substrate 30, at a front surface of the semiconductor substrate 30, a SBD structure configured by Schottky junctions between a front electrode (first electrode) 14 and an n-type drift region (first-conductivity-type region) 12, and pn diodes configured by pn junctions between the p⁺-type regions (first second-conductivity-type regions) 13 and the n-type drift region 12 are both present in an active region 10.

The n-type drift region 12 and the p⁺-type regions 13 are disposed substantially evenly in a substantially uniform pattern in the active region 10, in a plan view of the front surface of the semiconductor substrate 30. Portions of the n⁻-type drift region 12 and the p⁺-type regions 13, for example, are each disposed having, in a plan view of the device, a stripe-shape extending in a same direction parallel to the front surface of the semiconductor substrate 30, the portions of the n⁻-type drift region 12 and the p⁺-type regions 13 being disposed to repeatedly alternate with one another in a lateral direction orthogonal to a longitudinal direction in which the portions of the n-type drift region 12 and the p⁺-type regions 13 extend. Between the p⁺-type regions 13 that are adjacent to one another, the portions of the n-type drift region 12 are exposed at the front surface of the semiconductor substrate 30.

The active region 10 is a region through which current flows when the silicon carbide diode is on. The active region 10, for example, has a substantially rectangular shape in a plan view of the device and is disposed in substantially a center of the semiconductor substrate 30. An edge termination region 20 is a region between the active region 10 and an end of the semiconductor substrate 30; the edge termination region 20 surrounds the periphery of the active region 10 in a plan view of the device. The edge termination region 20 is a region of the n-type drift region 12; the edge termination region 20 mitigates electric field of the front side of the semiconductor substrate 30 and sustains a breakdown voltage. The breakdown voltage is a voltage limit at which no malfunction or destruction of the device occurs.

In the edge termination region 20, a voltage withstanding structure such as a junction termination extension (JTE) structure is disposed. The JTE structure is a voltage withstanding structure having a substantially rectangular shape surrounding the periphery of the active region 10 in a plan view and having multiple p-type regions (in FIGS. 1 and 3, only a p⁻-type region 22 is depicted) of differing doping concentrations, disposed in descending order of doping concentration in a direction from an inner side (a center-side of the semiconductor substrate 30) to an outer side (the end of the semiconductor substrate 30).

Further, the field limiting ring ((FLR) second second-conductivity-type region) 21 is disposed in a connecting region 20a of the edge termination region 20.

The FLR 21 is a p⁺-type region surrounding the periphery of the active region 10 in a substantially rectangular shape in a plan view of the device; the FLR 21 extends from the connecting region 20a of the edge termination region 20, in a direction to the end of the semiconductor substrate 30 to be in contact with the p⁻-type region 22. The FLR 21 may be in contact with the p⁺-type regions 13 in the longitudinal direction in which the p⁺-type regions 13 extend in the stripe-shapes.

The connecting region 20a of the edge termination region 20 is a region between the active region 10 and a later-described field oxide film 15; the connecting region 20a surrounds the periphery of the active region 10 in a plan view of the device and connects the active region 10 and the voltage withstanding structure portion of the edge termination region 20. The voltage withstanding structure portion of the edge termination region 20 is a portion of the edge termination region 20, from an inner peripheral end of the field oxide film 15 to the end of the semiconductor substrate 30 (chip end), the portion in which predetermined voltage withstanding structures such as an n⁺-type channel stopper region (not depicted) and the JTE structure are disposed.

The front electrode 14 is provided on the front surface of the semiconductor substrate 30, in the active region 10. The front electrode 14 is in contact with the n⁻-type drift region 12 and the p⁺-type regions 13 and is electrically connected to the n⁻-type drift region 12 and the p⁺-type regions 13. On the front surface of the semiconductor substrate 30, a passivation film (not depicted) is provided. The passivation film has a function of protecting the front electrode 14 and device structures in the semiconductor substrate 30, at the front surface of the semiconductor substrate 30.

The passivation film has an opening that exposes a portion of the front electrode 14. The portion of the front electrode 14 exposed in the opening of the passivation film functions as a bonding pad. The bonding pad, for example, is disposed in the center of the semiconductor substrate 30. The bonding pad is bonded (joined) to a non-depicted aluminum (Al) wire, which is a common (typical) wiring connection when current is to be supplied to the bonding pad.

Next, a cross-section of the structure of the silicon carbide semiconductor device 40 according to the first embodiment is described. As describe above, the silicon carbide semiconductor device 40 according to the first embodiment includes the JBS structure and the SBD structure of the silicon carbide diode, in the active region 10 of the semiconductor substrate 30 containing silicon carbide and includes the JTE structure as a voltage withstanding structure in the edge termination region 20.

The semiconductor substrate 30 is an epitaxial substrate in which an n-type epitaxial layer constituting the n-type drift region 12 is stacked on a front surface of an n⁺-type starting substrate 11 containing silicon carbide. The n⁺-type starting substrate 11 constitutes an n⁺-type cathode region. The semiconductor substrate 30 has, as the front surface, a main surface that is a surface of the n-type drift region 12 (the surface of the n-type epitaxial layer constituting the n-type drift region 12) and has, as a back surface, a main surface that is a surface of the n⁺-type starting substrate 11 (a back surface of the n⁺-type starting substrate 11).

In the semiconductor substrate 30, at the front surface thereof, one or more of the p⁺-type regions 13 configuring the JBS structure are selectively provided in the active region 10. The p⁺-type regions 13 are provided between the front surface of the semiconductor substrate 30 and the n-type drift region 12. The p⁺-type regions 13 are exposed at the front surface of the semiconductor substrate 30 and are in contact with the n-type drift region 12.

In the semiconductor substrate 30, at the front surface thereof, the FLR 21, one or more p-type regions (herein, one (1): the p-type region 22) configuring the JTE structure and the n⁺-type channel stopper region (not depicted) are each selectively provided in the edge termination region 20. The FLR 21 is provided in an entire area of the connecting region 20a of the edge termination region 20; the FLR 21 extends from the connecting region 20a, in a direction to the end of the semiconductor substrate 30 and is in contact with the p-type region 22. The active region 10 is farther from the end of the semiconductor substrate 30 than is an inner peripheral end of the FLR 21.

The p-type region 22 is provided apart from the connecting region 20a of the edge termination region 20 and closer to the end of the semiconductor substrate 30 than is the FLR 21, the p-type region 22 being in contact with the FLR 21. The n⁺-type channel stopper region is provided closer to the end of the semiconductor substrate 30 than is the p⁻-type region 22 and is apart from the p⁻-type region 22. The n⁺-type channel stopper region is exposed at the end of the semiconductor substrate 30 (the chip end).

The FLR 21, the p-type region 22, and the n⁺-type channel stopper region are provided between the front surface of the semiconductor substrate 30 and the n-type drift region 12. The FLR 21, the p-type region 22, and the n⁺-type channel stopper region are exposed at the front surface of the semiconductor substrate 30 and are in contact with the n⁻-type drift region 12. Depths of the FLR 21, the p⁻-type region 22, and the n⁺-type channel stopper region, for example, may be a same depth as a depth of the p⁺-type regions 13.

The front surface of the semiconductor substrate 30 is covered by the field oxide film 15. The field oxide film 15, for example, may be a stacked film in which a thermal oxide film and a deposited oxide film are sequentially stacked. The thermal oxide film may enhance adhesion between the semiconductor substrate 30 and the field oxide film 15. The field oxide film 15 includes a deposited oxide film and thus, the field oxide film 15 may be formed in a shorter amount time than in an instance in which the field oxide film 15 is entirely a thermal oxide film.

In the field oxide film 15, a contact hole 15a that exposes nearly an entire portion of the front surface of the semiconductor substrate 30 in the active region 10 is provided. A sidewall (inner peripheral side-surface of the field oxide film 15) of the contact hole 15a of the field oxide film 15, for example, is substantially orthogonal to the front surface of the semiconductor substrate 30. The contact hole 15a of the field oxide film 15 is provided in an entire area from the active region 10 to the connecting region 20a of the edge termination region 20.

In the contact hole 15a of the field oxide film 15, the n-type drift region 12 and the p⁺-type regions 13 in the active region 10 and an inner peripheral portion of the FLR 21 in the edge termination region 20 are exposed. In the contact hole 15a of the field oxide film 15 on the front surface of the semiconductor substrate 30, the front electrode 14, which functions as an anode electrode, is provided along the front surface of the semiconductor substrate 30.

The front electrode 14 has a stacked structure in which a titanium film 31 and an aluminum alloy film (metal electrode film containing aluminum) 32 are sequentially stacked. In addition, the front electrode 14 has the nickel silicide (NiSi) films 33 (33a, 33b), which are the lowest layer of the front electrode 14 and selectively provided between the front surface of the semiconductor substrate 30 and the titanium film 31. The nickel silicide films 33 contain aluminum. The nickel silicide films 33 may contain carbon (C). The front electrode 14 may extend on the field oxide film 15, in a direction to the end of the semiconductor substrate 30.

The titanium film 31 is provided on an entire portion of the front surface of the semiconductor substrate 30 in the contact hole 15a and is in contact with the n⁻-type drift region 12. Portions of the titanium film 31 forming junctions with the n⁻-type drift region 12 constitute Schottky electrodes that form the Schottky junctions with the n-type drift region 12. The titanium film 31 may extend on the field oxide film 15, in a direction to the end of the semiconductor substrate 30 and, for example, may terminate at a position facing the FLR 21 in a depth direction of the device.

The aluminum alloy film 32 covers an entire surface of the titanium film 31, is electrically connected to the titanium film 31, and via the titanium film 31, is electrically connected to the nickel silicide films 33. The aluminum alloy film 32 may extend on the field oxide film 15, to a position closer to the end of the semiconductor substrate 30 than is the titanium film 31 and, for example, may terminate at a position facing the p-type region 22 in the depth direction. The aluminum alloy film 32, for example, is an aluminum-silicon (AISi) film. Instead of the aluminum alloy film 32, an aluminum film may be provided.

The nickel silicide films 33 include first nickel silicide films 33a provided between the titanium film 31 and the p⁺-type regions 13 and second nickel silicide films 33b provided between the FLR 21 and the titanium film 31. The first nickel silicide films 33a are ohmic electrodes in ohmic contact with the p⁺-type regions 13. The first nickel silicide films 33a have a function of increasing the amount of surge current that is lead out from the semiconductor substrate 30 to the front electrode 14 (lead-out amount) and thereby enhancing surge current tolerance, the surge current being generated in the semiconductor substrate 30 and flowing in the forward direction when surge voltage is applied.

The first nickel silicide films 33a are provided in surface regions of the front surface of the semiconductor substrate 30, are in contact with the p⁺-type regions 13 in the depth direction, and may protrude from the front surface of the semiconductor substrate 30 in a direction away from the front surface of the semiconductor substrate 30.

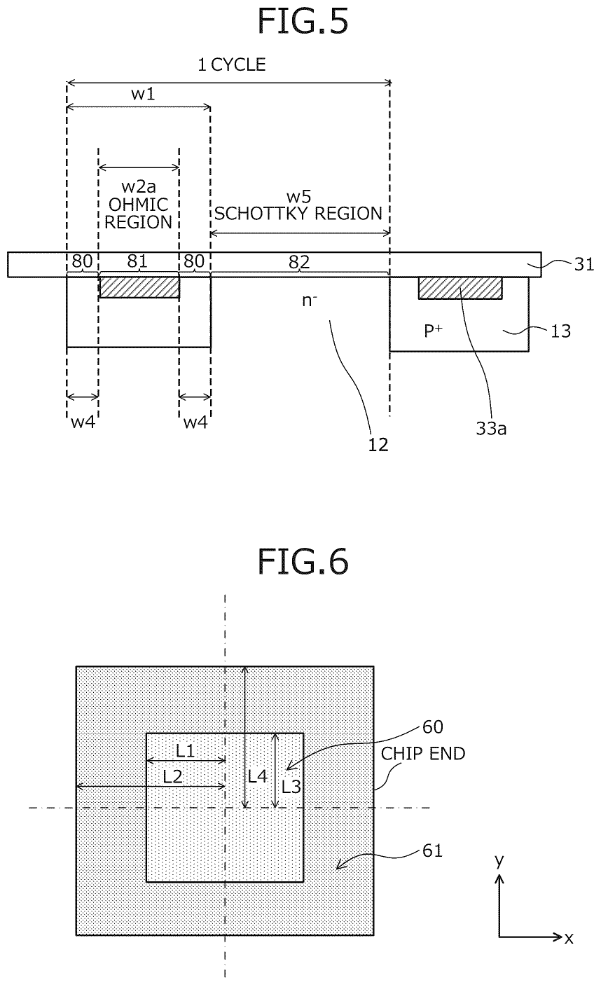

FIG. 5 is a cross-sectional view depicting, in detail, the structure of a region S surrounded by a dashed line in FIG. 3. An area where the first nickel silicide films 33a on the p⁺-type regions 13 in FIG. 1 are provided is similar to FIG. 5. As depicted in FIG. 5, a width w2a of each of the first nickel silicide films 33a is narrower than a width w1 of each of the p⁺-type regions 13. Preferably, a width of one side w4 (one half) of a difference of the width w2a of the first nickel silicide films 33a and the width w1 of the p⁺-type regions 13 may be in a range of 0.1 μm to 5.0 μm. The width w2a of the first nickel silicide films 33a is narrower than the width w1 of the p⁺-type regions 13 and thus, the p⁺-type regions 13 are exposed at the front surface of the semiconductor substrate 30. As a result, the high-resistance Schottky junctions of the p⁺-type regions 13 and the titanium film 31 are formed.

The active region 10 is configured by: high-resistance junction regions 80 where the titanium film 31 is in contact with the p⁺-type regions 13 configuring JBS structure, each of the high-resistance junction regions 80 having a stripe-shape; ohmic regions 81 where the titanium film 31 is in contact with the first nickel silicide films 33a, the ohmic regions 81 having a resistance lower than a resistance of the high-resistance junction regions 80; and Schottky regions 82 where the titanium film 31 is in contact with the n⁻-type drift region 12, each of the Schottky regions 82 having a stripe-shape and a resistance lower than the resistance of the ohmic regions 81. In the active region 10, cycles repeat, each including four regions: one of the ohmic regions 81; two of the high-resistance junction regions 80, said two being disposed in contact with ends of said one of the ohmic regions 81 in a direction orthogonal to a direction in which the p⁺-type regions 13 extend in the stripe-shapes; and one of the Schottky regions 82. A stripe-shape is a long, thin rectangle shorter in a lateral direction than in a longitudinal direction like the portions of the n⁻-type drift region 12 depicted in FIGS. 2A and 2B. Further, the ohmic regions 81 may have dot-like shapes. A dot-like shape is a square having substantially the same length in a lateral direction and in a longitudinal direction like the first nickel silicide films 33a (the ohmic regions 81) depicted in FIGS. 2B and 4B. In an instance of the dot-like shape, preferably, an interval between any adjacent two of the ohmic regions 81 (the nickel silicide films 33) may be narrow. Preferably, for example, the interval may be set to be not more than 5 μm.

With the described cyclic structure, the ohmic regions 81 are uniform in the active region 10 overall and may be disposed densely. Thus, when large surge current flows in the forward direction in the semiconductor substrate, the surge current may be dispersed and IFSM characteristics may be increased.

Further, as depicted in FIGS. 2A, 2B, 4A, and 4B, the p⁺-type regions 13 are connected to a guard ring (in FIGS. 2A, 2B, 4A, and 4B, the FLR 21) provided in the edge termination region 20. Further, in an instance in which the second nickel silicide films 33b are provided in the guard ring, the first nickel silicide films 33a of the ohmic regions 81 suffice to be connected to the second nickel silicide films 33b. In other words, the ohmic regions 81 and the high-resistance junction regions 80 suffice to be connected to the edge termination region 20.

Further, as depicted in FIG. 1, in the active region 10, the high-resistance junction regions 80 are provided on both sides of each of the ohmic regions 81 in the direction orthogonal to the direction in which the p⁺-type regions 13 extend in the stripe-shapes and in the active region 10, the ohmic regions 81 are not connected to one another. In other words, between any adjacent ones of the first nickel silicide films 33a, the high-resistance junction regions 80 and the Schottky regions 82 are present. As described, in the first embodiment, wide ohmic regions spanning multiple stripe-shapes of the ohmic regions 81 are not present. As a result, the area of the ohmic regions 81 does not increase and thus, Vf characteristics may be maintained.

Such a structure may be formed using a nickel silicide generated by causing a metal material film in which nickel, aluminum, and nickel are sequentially deposited in the order stated and surface regions of the semiconductor substrate 30 to react with one another by a heat treatment. The first nickel silicide films 33a, which have a low resistance, are formed by self-alignment by removing (etching) portions (portions excluding a heated and reacted layer) of the metal material film not converted into a silicide. The metal material film in which nickel, aluminum, and nickel are sequentially deposited is used, whereby low-resistance p-type ohmic electrodes are formed. Further, the first nickel silicide films 33a are formed by self-alignment and thus, on an inner side of the JBS structure, which has a width of a few μm, the ohmic electrodes are formed, thereby, enabling the Vf characteristics to be maintained. As described, the ohmic regions 81, which have low resistance, may be formed without decreasing the area of the Schottky regions 82 and thus, the IFSM characteristics may be improved while maintaining the Vf characteristics.

Further, the width w2a of the first nickel silicide films 33a is narrower than the width w1 of the p⁺-type regions 13, whereby a design margin may be set to enhance the accuracy of the positioning of a mask used when the first nickel silicide films 33a are formed. As a result, the first nickel silicide films 33a may be disposed accurately at positions facing the p⁺-type regions 13 in the depth direction.

FIG. 6 is a plan view depicting the chip outer peripheral portion and the chip center portion when the silicon carbide semiconductor device according to the first embodiment is viewed from the front side of the semiconductor substrate. In FIG. 6, for the sake of description of the chip outer peripheral portion and the chip center portion, the structure of the [A] the silicon carbide semiconductor device 40 is not depicted. A chip center portion 60 is a region provided in the center of the chip and suffices to be a region substantially in the center of the chip, spanning from a center of each edge of the chip ¼ to ¾ to an end of said each edge of the chip. A chip outer peripheral portion 61 is a region provided in an outer periphery of the chip and is a region outside the chip center portion 60 of the silicon carbide semiconductor device. More specifically, in an x-direction, a length from the chip center (in FIG. 6, point of intersection of a long dashed dotted line in the x-direction and a long dashed dotted line in a y-direction) to the chip end is assumed as “L2” and in the x-direction, a length from the chip center to an end of the chip center portion 60 is assumed as “L1”, where, ¼≤L1/L2≤¾ is satisfied. Similarly, for the y-direction as well, in the y-direction, a length from the chip center to the chip end is assumed as “L4” and in the y-direction, a length from the chip center to the end of the chip center portion 60 is assumed as “L3”, where, ¼≤L3/L4≤¾ is satisfied.

In the first embodiment, the positions where the nickel silicide films 33 are provided change depending on a doping concentration of the n-type drift region 12. When the doping concentration of the n-type drift region 12 is a high concentration of 1.0×10¹⁶/cm³ to 9.0×10¹⁶/cm³, a greater number of the nickel silicide films 33 is provided in the chip outer peripheral portion 61 than in the chip center portion 60, and a greater number of the ohmic regions 81 where the nickel silicide films 33 and the p⁺-type regions 13 form ohmic junctions is provided in the chip outer peripheral portion than in the chip center portion. For example, as depicted in FIGS. 2A and 2B, the nickel silicide films 33 may be provided in the chip outer peripheral portion; the ohmic regions 81 may be provided only in the chip outer peripheral portion; and a greater number of the ohmic regions 81 may be provided in the chip outer peripheral portion than in the chip center portion.

On the other hand, when the doping concentration of the n-type drift region 12 is a low concentration in a range of 1.0×10¹⁵/cm³ or more but less than 1.0×10¹⁶/cm³, a greater number of the nickel silicide films 33 is provided in the chip center portion than in the chip outer peripheral portion and a greater number of the ohmic regions 81 is provided in the chip center portion than in the chip outer peripheral portion. For example, as depicted in FIGS. 4A and 4B, the nickel silicide films 33 may be provided in the chip center portion; the ohmic regions 81 may be provided only in the chip center portion; and a greater number of the ohmic regions 81 may be provided in the chip center portion than in the chip outer peripheral portion.

Further, the nickel silicide films 33 may have a stripe-shape as depicted in FIGS. 2A and 4A or may have a dot-shape as depicted in FIGS. 2B and 4B. Thus, the ohmic regions 81 may have a stripe-shape or may have a dot-shape.

As described, in the first embodiment, positions where the ohmic regions 81 are disposed changes depending on the doping concentration of the n⁻-type drift region 12, whereby current is easily dispersed throughout the chip during surges and local increases in generated heat may be suppressed. When the doping concentration of the n⁻-type drift region 12 is a high concentration, surge current concentrates directly beneath wiring or in the chip center and thus, a greater number of the ohmic regions 81 is provided in the chip center portion 60 than in the chip outer peripheral portion 61, whereby destruction in the chip center may be prevented. Further, when the doping concentration of the n-type drift region 12 is a low concentration, surge current concentrates in the outer periphery of the chip and thus, a greater number of the ohmic regions 81 is provided in the chip center portion 60, whereby destruction in the outer periphery of the chip may be prevented.

Further, when the doping concentration of the n′-type drift region 12 is a high concentration, in the chip outer peripheral portion 61, a rate (percentage) of the area of the high-resistance junction regions 80 relative to the area of the p⁺-type regions 13 may be preferably, 35% or more and more preferably, may be in a range of 35% to 90%. Further, in the chip outer peripheral portion 61, a rate of the area of the high-resistance junction regions 80 relative to the area of the active region 10 may be, preferably, in a range of 15% to 40%. Further, in the chip outer peripheral portion 61, a rate of the area of the high-resistance junction regions 80 relative to the area of the chip, preferably, may be in a range of 15% to 40%. The rate of the area of the high-resistance junction regions 80 is set to be within these ranges, whereby both enhanced surge current tolerance and low Vf characteristics may be achieved.

Furthermore, when the doping concentration of the n-type drift region 12 is a low concentration, in the chip center portion 60, the rate of the area of the high-resistance junction regions 80 relative to the area of the p⁺-type regions 13 may be, preferably, 35% or more and more preferably may be in a range of 35% to 90%. Further, in the chip center portion 60, the rate of the area of the high-resistance junction regions 80 relative to the area of the active region 10 may be, preferably, in a range of 15% to 40%. Further, in the chip center portion 60, the rate of the area of the high-resistance junction regions 80 relative to the area of the chip may be, preferably in a range of 15% to 40%. The rate of the area of the high-resistance junction regions 80 is set to be within these ranges, whereby both enhanced surge current tolerance and low Vf characteristics may be achieved.

Here, the rate of the area of the high-resistance junction regions 80 relative to the area of the p⁺-type regions 13 is the area of the high-resistance junction regions 80/(the area of the p⁺-type regions 13); and the rate of the area of the high-resistance junction regions 80 relative to the area of the active region 10 is the area of the high-resistance junction regions 80/(the area of the Schottky regions 82+the area of the ohmic regions 81+the area of the high-resistance junction regions 80). Similarly, the rate of the area of the high-resistance junction regions 80 relative to the area of the chip is obtained by the area of the high-resistance junction regions 80/(the area of the Schottky regions 82+the area of the ohmic regions 81+the area of the high-resistance junction regions 80+the area of the edge termination region 20).

The second nickel silicide films 33b are ohmic electrodes in ohmic contact with the FLR 21. The second nickel silicide films 33b may be provided in nearly an entire area of the surface of the FLR 21 in the connecting region 20a of the edge termination region 20. The second nickel silicide films 33b are in contact with the field oxide film 15, at a sidewall of the field oxide film 15. The second nickel silicide films 33b, similar to the first nickel silicide films 33a, have a function of increasing the amount of surge current lead out, thereby, enhancing surge current tolerance.

The second nickel silicide films 33b are provided, thereby enabling ohmic electrodes having a same function as a function of the first nickel silicide films 33a disposed in the connecting region 20a of the edge termination region 20. As a result, even in an instance in which chip size (dimensions in a plane parallel to the front surface of the semiconductor substrate 30) is small, the area of the ohmic junctions between the front electrode 14 and the semiconductor substrate 30 may be sufficiently ensured for an amount just necessary to obtain a predetermined surge current tolerance by the total junction area of the first and second nickel silicide films 33a, 33b and the semiconductor substrate 30.

Further, the second nickel silicide films 33b extend toward the chip end, to positions so as to be in contact with the field oxide film 15, whereby the area of the ohmic junctions between the FLR 21 and the second nickel silicide films 33b may be maximized. As a result, a width w2b of the second nickel silicide films 33b is substantially a same as a width w3 of the connecting region 20a of the edge termination region 20 and as described above, the second nickel silicide films 33b may be provided in nearly an entire area of the surface of the FLR 21 in the connecting region 20a of the edge termination region 20.

Further, the width w2b of the second nickel silicide films 33b is substantially the same as the width w3 of the connecting region 20a of the edge termination region 20, whereby similar to an instance in which the width w2a of the first nickel silicide films 33a is substantially the same as the width w1 of the p⁺-type regions 13, reduced forward voltage of the silicon carbide diode achieved. The width w2b of the second nickel silicide films 33b, for example, may be narrower than the width w3 of the connecting region 20a of the edge termination region 20. A reason for this is the same as the reason the width w2a of the first nickel silicide films 33a may be narrower than the width w1 of the p⁺-type regions 13.

The second nickel silicide films 33b may be at the front surface of the semiconductor substrate 30 so as to be in contact with the FLR 21 in the depth direction and protrude from the front surface of the semiconductor substrate 30, in a direction away from the front surface of the semiconductor substrate 30.

Portions of the front surface of the semiconductor substrate 30 other than portions in contact with the front electrode 14 are covered by the field oxide film 15. At an outermost aspect of the front surface of the semiconductor substrate 30, the passivation film containing a polyimide is provided. Here, a channel stopper electrode in contact with and electrically connected to the n⁺-type channel stopper region may be provided at an upper portion of the n⁺-type channel stopper region. The channel stopper electrode, for example, may be an aluminum alloy film formed concurrently with the aluminum alloy film 32.

The passivation film is a protective film protecting the front electrode 14 and the field oxide film 15. In the passivation film, in the active region 10, an opening exposing a portion of the aluminum alloy film 32 is provided. The portion of the front electrode 14 exposed in the opening of the passivation film functions as the bonding pad. A back electrode (second electrode) 19 is provided in an entire area of the back surface (the back surface of the n⁺-type starting substrate 11) of the semiconductor substrate 30 and is electrically connected to the n⁺-type starting substrate 11.

The silicon carbide semiconductor device 40 according to the first embodiment is manufactured by a method similar to the manufacturing method described in Japanese Laid-Open Patent Publication No. 2021-93522. For example, manufacture is as follows. First, as the n⁺-type starting substrate (semiconductor wafer) 11, a 4-layer periodic hexagonal crystal (4H-SiC) silicon carbide substrate doped with nitrogen (N) to be, for example, about 5×10¹⁸/cm³ is prepared. Next, on the front surface of the n⁺-type starting substrate 11, the n-type epitaxial layer doped with nitrogen to about 1.8×10¹⁶/cm³ and constituting the n-type drift region 12 is grown, thereby forming the semiconductor substrate 30.

Next, in the semiconductor substrate 30, at the front surface thereof, one or more of the p⁺-type regions 13 configuring the JBS structure and the FLR 21 are each selectively formed in the active region 10 by photolithography and ion-implantation of a p-type dopant such as aluminum. Next, an entire area of the front surface of the semiconductor substrate 30 is covered and protected by, for example, a carbon (C) protective film and thereafter, the ion-implanted dopants area activated by a heat treatment.

Next, an oxide film is formed in the entire area of the front surface of the semiconductor substrate 30. Next, the oxide film is selectively removed by photolithography and etching, thereby forming openings. Next, for example, a metal material film is formed on the portions of the front surface (surface) of the semiconductor substrate 30 in the openings of the oxide film, from the surface of the oxide film by a sputtering technique.

Thereafter, the metal material film is sintered by a heat treatment (first sintering), thereby generating an aluminum-nickel-silicon (Al—Ni—Si) compound in the opening of the oxide film. Next, excess metal (excess portion) in the openings of the oxide film and on the oxide film is removed.

Next, the Al—Ni—Si compound is sintered by a heat treatment (second sintering). A nickel silicide is generated in the Al—Ni—Si compound by this heat treatment, whereby the Al—Ni—Si compound is converted into the nickel silicide films 33 that are in ohmic contact with the semiconductor substrate 30.

In the first embodiment, by changing the positions of the openings of the oxide film from the manufacturing method described in Japanese Laid-Open Patent Publication No. 2021-93522, in an instance in which the doping concentration of the n-type drift region 12 is a high concentration, a greater number of the nickel silicide films 33 is provided in the chip outer peripheral portion than in the chip center portion and a greater number of the ohmic regions 81 is provided in the chip outer peripheral portion 61 than in the chip center portion 60. Further, in an instance in which the doping concentration of the n-type drift region 12 is a low concentration, a greater number of the nickel silicide films 33 is provided in the chip center portion 60 than in the chip outer peripheral portion 61 and a greater number of the ohmic regions 81 is provided in the chip center portion 60 than in the chip outer peripheral portion 61.

Next, etching is performed using a resist film as a mask, thereby forming in the field oxide film 15, the contact hole 15a that penetrates through the field oxide film 15, in the depth direction. Next, for example, by a physical vapor deposition (PVD) method such as sputtering, from the surface of the field oxide film 15, the titanium film 31 is formed in an entire area of the surface of the contact hole 15a to the front surface of the semiconductor substrate 30. Next, by photolithography and etching, the titanium film 31 is left only in the contact hole 15a.

Next, for example, the titanium film 31 is sintered for about 10 minutes by a heat treatment at a temperature of about 500 degrees C. Next, for example, by a physical vapor deposition (PVD) method such as sputtering, from the surface of the titanium film 31, in an entire area of the surface, to the surface of the field oxide film 15, for example, the aluminum alloy film having a thickness of about 5 μm is formed. Next, by photolithography and etching, the aluminum alloy film is selectively removed and left at the surface of the titanium film 31 as the aluminum alloy film 32 constituting the front electrode 14.

Next, for example, by a physical vapor deposition (PVD) method such as sputtering, nickel, titanium, etc. is deposited in an entire area of the back surface (the back surface of the n⁺-type starting substrate 11) of the semiconductor substrate 30 and thereafter, the back electrode 19 is formed by laser annealing. Subsequently, the protective film at the front surface of the semiconductor substrate 30 is removed and thereafter, the semiconductor substrate 30 is diced (cut) into individual chips, thereby completing the silicon carbide semiconductor device 40 of the first embodiment.

As described above, according to the first embodiment, in an instance in which the doping concentration of the n-type drift region is a low concentration, surge current concentrates in the outer periphery of the chip and thus, a greater number of the ohmic regions is provided in the chip center portion, whereby destruction in the outer periphery of the chip may be prevented. Further, in an instance in which the doping concentration of the n-type drift region is a high concentration, surge current concentrates directly beneath wiring or in the chip center and thus, a greater number of the ohmic regions is provided in the chip outer peripheral portion, whereby destruction in the chip center may be prevented.

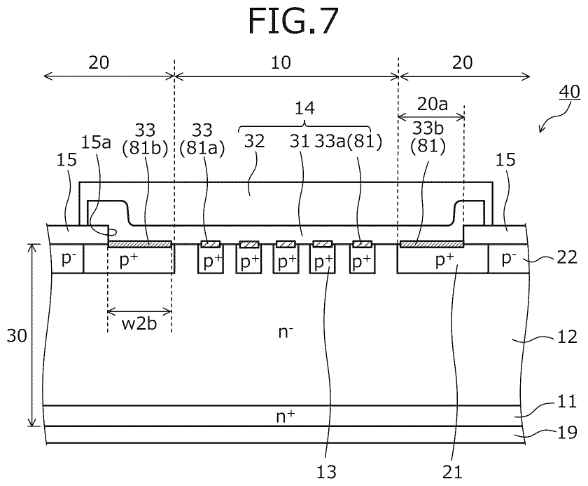

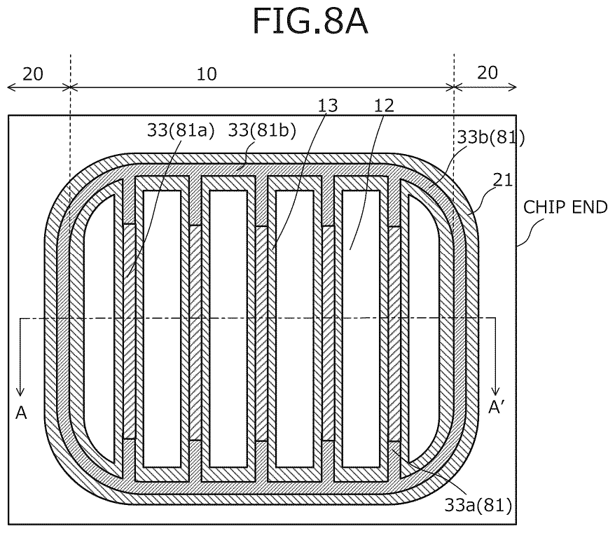

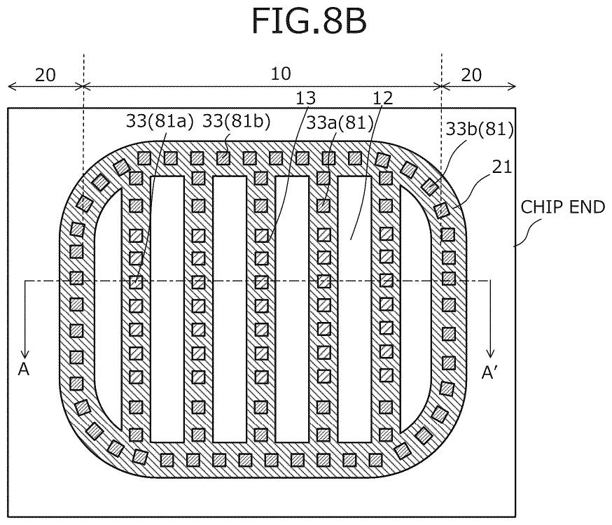

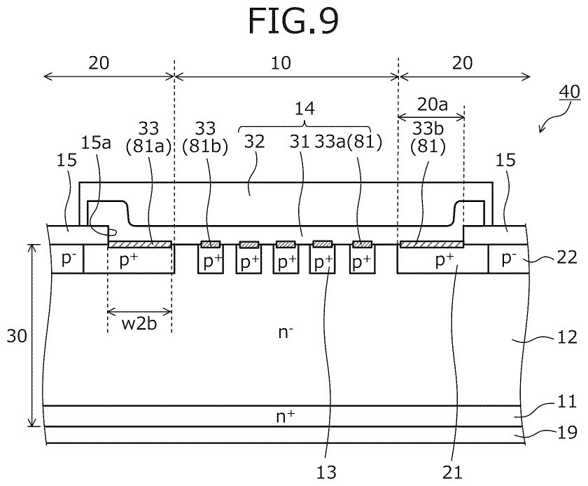

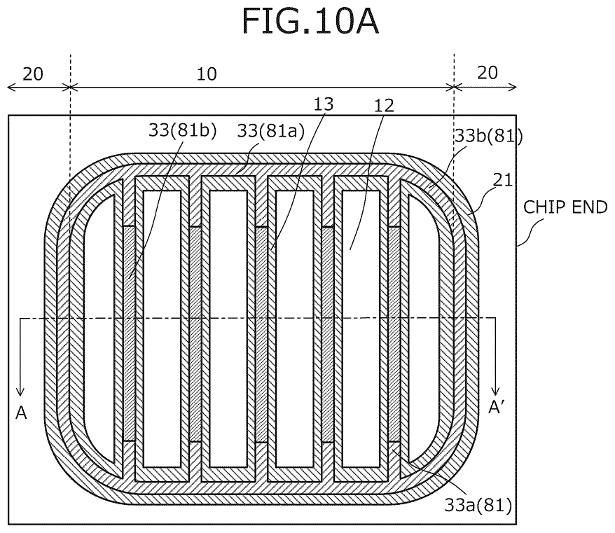

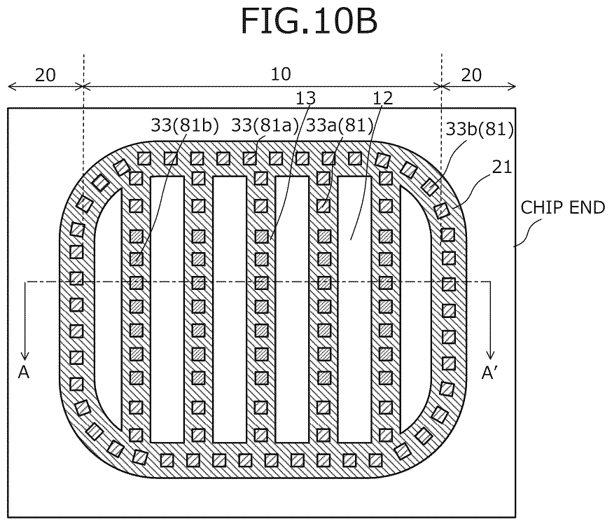

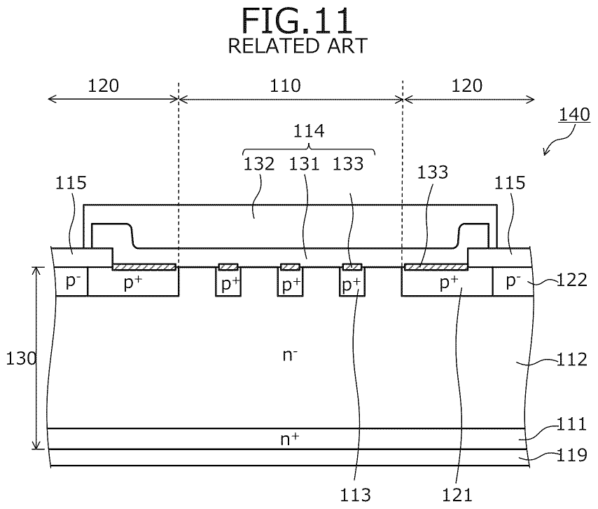

Next, the semiconductor device according to a second embodiment is described. FIG. 7 is a cross-sectional view depicting the structure in an instance in which the drift layer of the silicon carbide semiconductor device according to the second embodiment has a low concentration. FIG. 8A is a plan view of a layout when the silicon carbide semiconductor device according to the second embodiment in FIG. 7 is viewed from the front side of the semiconductor substrate. FIG. 8B is a plan view of another layout when the silicon carbide semiconductor device according to the second embodiment in FIG. 7 is viewed from the front side of the semiconductor substrate. FIG. 9 is a cross-sectional view depicting the structure in an instance in which the drift layer of the silicon carbide semiconductor device according to the second embodiment has a high concentration. FIG. 10A is a plan view of a layout when the silicon carbide semiconductor device according to the second embodiment in FIG. 9 is viewed from the front side of the semiconductor substrate. FIG. 10B is a plan view of another layout when the silicon carbide semiconductor device according to the second embodiment in FIG. 9 is viewed from the front side of the semiconductor substrate.

FIGS. 8A, 8B, 10A, and 10B are plan views depicting examples of the layout of the p⁺-type regions configuring the JBS structure, the field limiting ring 21, and the nickel silicide films 33. A cross-sectional view of the silicon carbide semiconductor device depicted in FIG. 7 corresponds to cutting line A-A′ in FIGS. 8A and 8B. A cross-sectional view of the silicon carbide semiconductor device depicted in FIG. 9 corresponds to cutting line A-A′ in FIGS. 10A and 10B.

In the second embodiment, the nickel silicide films 33, similar to the conventional silicon carbide semiconductor device 140 (refer to FIG. 12), differ from the first embodiment in that the nickel silicide films 33 are provided on the p⁺-type regions 13 and the field limiting ring 21. However, in the second embodiment, contact resistance of the nickel silicide films 33 varies depending on the doping concentration of the n-type drift region 12. In the second embodiment, other than the nickel silicide films 33, the structure is the same as the structure in the first embodiment.

When the doping concentration of the n-type drift region 12 is a low concentration of 1.0×10¹⁵/cm³ or greater but less than 1.0×10¹⁶/cm³, as depicted in FIGS. 7, 8A, and 8B, the nickel silicide films 33 constituting high-resistance ohmic regions 81b are provided in the chip outer peripheral portion 61, while the nickel silicide films 33 constituting low-resistance ohmic regions 81a are provided in the chip center portion 60.

On the other hand, when the doping concentration of the n-type drift region 12 is a high concentration in a range of 1.0×10¹⁶/cm³ to 9.0×10¹⁶/cm³, as depicted in FIGS. 9, 10A, and 10B, the nickel silicide films 33 constituting the low-resistance ohmic regions 81a are provided in the chip outer peripheral portion 61, while the nickel silicide films 33 constituting the high-resistance ohmic regions 81b are provided in the chip center portion 60. The low-resistance ohmic regions 81a have a contact resistance that is at least 5×10⁻⁵ Ω/cm² but less than 5×10⁻⁴ Ω/cm² and the high-resistance ohmic regions 81b have a contact resistance that is in a range of 5×10⁻⁴ Ω/cm² to 5×10⁻³ Ω/cm².

Further, the nickel silicide films 33 may each have a stripe-shape as depicted in FIGS. 8A and 10A or may each have a dot-like shape as depicted in FIGS. 8B and 10B. Thus, the low-resistance ohmic regions 81a and the high-resistance ohmic regions 81b may have stripe-shapes or dot-like shapes.

As described, in the second embodiment, the contact resistance of the nickel silicide films 33 of the ohmic regions 81 is different depending on the doping concentration of the n-type drift region 12. As a result, current is easily dispersed throughout the chip during surges and local increases in generated heat may be suppressed. When the doping concentration of the n-type drift region 12 is a low concentration, surge current concentrates in the outer periphery of the chip and thus, the nickel silicide films 33 that constitute the low-resistance ohmic regions 81a are provided in the chip center portion 60, whereby destruction in the outer periphery of the chip may be prevented. Further, when the doping concentration of the n-type drift region 12 is a high concentration, surge current concentrates directly beneath wiring or in the chip center and thus, the nickel silicide films 33 that constitute the low-resistance ohmic regions 81a are provided in the chip outer peripheral portion 61, whereby destruction in the chip center may be prevented.

The silicon carbide semiconductor device 40 according to the second embodiment, similar to the first embodiment, is manufactured by a method similar to the manufacturing method described in Japanese Laid-Open Patent Publication No. 2021-93522. In the second embodiment, when the first sintering is performed to the metal material film containing AI, Ni, the temperature is changed, whereby the low-resistance ohmic regions 81a and the high-resistance ohmic regions 81b are formed. The higher is the composition ratio of Si in the nickel silicide, the lower is the resistance and, for example, NiSiₓ (x>2) has a lower resistance than the resistance of NiSi. Thus, the low-resistance ohmic regions 81a are formed by a higher temperature than the annealing temperature for the high-resistance ohmic regions 81b so that the composition ratio of Si thereof is higher than the composition ratio of Si in the high-resistance ohmic regions 81b.

When the doping concentration of the n-type drift region 12 is a low concentration, in the chip outer peripheral portion 61, the annealing temperature is set to be a low temperature at least 800 degrees C. but less than 1000 degrees C. and the nickel silicide films 33 constituting the high-resistance ohmic regions 81b are formed, while in the chip center portion 60, the annealing temperature is set to be a high temperature in a range of 1000 degrees C. to 1200 degrees C. and the nickel silicide films 33 constituting the low-resistance ohmic regions 81a are formed.

On the other hand, when the doping concentration of the n-type drift region 12 is a high concentration, in the chip outer peripheral portion 61, the annealing temperature is set to be a high temperature in a range of 1000 degrees C. to 1200 degrees C. and the nickel silicide films 33 constituting the low-resistance ohmic regions 81a are formed, while in the chip center portion 60, the annealing temperature is set to be a low temperature at least 800 degrees C. but less than 1000 degrees C. and the nickel silicide films 33 constituting the high-resistance ohmic regions 81b are formed.

In the chip center portion 60 and the chip outer peripheral portion 61, the annealing temperature may be changed by changing the irradiation conditions of the laser in the laser annealing. Further, the low-temperature annealing may be performed in a furnace and the high-temperature annealing may be performed by laser annealing. Further, while laser emission output varies according to metal, etc., preferably, the output may be in a range of 1 J/cm² to 5 J/cm² and more preferably, may be in a range of 2 J/cm² to 3 J/cm².

As described above, according to the second embodiment, when the doping concentration of the n⁻-type drift region is a low concentration, surge current concentrates in the outer periphery of the chip and thus, the nickel silicide film constituting the low-resistance ohmic regions in the chip center portion or directly beneath wiring is provided, whereby destruction in the outer periphery of the chip may be prevented. Further, when the doping concentration of the n-type drift region is a high concentration, surge current concentrates in the chip center and thus, the nickel silicide film constituting the low-resistance ohmic regions is provided in the chip outer peripheral portion, whereby destruction in the chip center may be prevented.

In the first embodiment and the second embodiment, the first sintering is performed to the metal material film, whereby an aluminum-nickel-silicon (AI-Ni—Si) compound is generated in the opening of the oxide film and the second sintering is performed on the Al—Ni—Si compound, whereby a nickel silicide is generated in the Al—Ni—Si compound. Thus, the metal material film contains Ni for forming a silicide and may further contain Al, molybdenum (Mo), or titanium for forming a carbide.

In the foregoing, the present disclosure is not limited to the embodiments described above, various modifications within a range not departing from the spirit of the disclosure are possible, and application is possible to semiconductor devices having ohmic electrodes in ohmic contact with p-type regions disposed in a predetermined pattern.

In particular, for example, the present disclosure is useful for silicon carbide semiconductor devices with a configuration for reducing contact resistance between p-type regions (or p⁺-type contact regions disposed between a main surface of a semiconductor substrate and the p-type regions) and ohmic electrodes, and semiconductor devices with a structure in which an oxide film and ohmic electrodes in ohmic contact with p-type regions are in contact with each other.

According to the present disclosure above, when the doping concentration of the n-type drift region (first-conductivity-type region) is a low concentration, surge current concentrates in the chip outer peripheral portion and thus, a greater area or number of ohmic regions are provided in the chip center portion, whereby destruction in the outer periphery of the chip may be prevented. Further, when the doping concentration of the n′-type drift region is a high concentration, surge current concentrates directly beneath wiring or in the chip center and thus, a greater area or number of ohmic regions are provided in the chip outer peripheral portion, whereby destruction in the chip center may be prevented.

The semiconductor device and the method of manufacturing a semiconductor device according to the present disclosure achieve an effect in that low-resistance ohmic electrodes are formed, whereby the surge current tolerance may be increased while maintaining low Vf characteristics and reducing leakage current.

As described, the semiconductor device and the method of manufacturing a semiconductor device according to the present disclosure are useful for power semiconductor device used in power converting equipment, power source devices of various types of industrial machines and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having an active region and a termination region surrounding a periphery of the active region, the semiconductor substrate having a first main surface and a second main surface opposite to each other;
a first-conductivity-type region provided in the semiconductor substrate and exposed at the first main surface of the semiconductor substrate;
a plurality of second-conductivity-type regions each selectively provided in the first-conductivity-type region, at the first main surface of the semiconductor substrate in the active region; and
a plurality of silicide films each in ohmic contact with a portion of a corresponding one of the plurality of second-conductivity-type regions, wherein
the active region has a chip center portion provided at a center thereof, and a chip outer peripheral portion surrounding a periphery of the chip center portion,
in a case where the first-conductivity-type region is in a low concentration condition in which a doping concentration of the first-conductivity-type region is 1.0×10¹⁵/cm³ or more but less than 1.0×10¹⁶/cm³, a total area or a total number of the plurality of silicide films provided in the chip center portion is greater than is a total area or a total number of the plurality of silicide films provided in the chip outer peripheral portion, and
in a case where the first-conductivity-type region is in a high concentration condition in which the doping concentration of the first-conductivity-type region is in a range of 1.0×10¹⁶/cm³ to 9.0×10¹⁶/cm³, the total area or the total number of the plurality of silicide films provided in the chip center portion is less than is the total area or the total number of the plurality of silicide films provided in the chip outer peripheral portion.

2. The semiconductor device according to claim 1, further comprising:
a first electrode provided at the first main surface of the semiconductor substrate; and
a second electrode provided at the second main surface of the semiconductor substrate, wherein
the active region has:
a plurality of Schottky regions each formed by the first electrode and by each of the plurality of first-conductivity-type regions that contact each other,
a plurality of ohmic regions each formed by the first electrode and by each of the plurality of silicide films that contact each other, and
a plurality of high-resistance junction regions each formed by the first electrode and by each of the plurality of second-conductivity-type regions that contact each other.

3. The semiconductor device according to claim 2, wherein
a distance in the chip center portion measured from the center of the active region to an edge of the chip center portion is in a range of ¼ to ¾ of a distance from the center of the active region to an end of the semiconductor substrate in each of a first direction and a second direction that are orthogonal to each other and parallel to the first main surface.

4. The semiconductor device according to claim 3, wherein
in the case where the first-conductivity-type region is in the low concentration condition, a total area or a total number of the plurality of ohmic regions provided in the chip center portion is greater than is a total area or a total number of the plurality of ohmic regions provided in the chip outer peripheral portion, and
in the case where the first-conductivity-type region is in the high concentration condition, the total area or the total number of the plurality of ohmic regions provided in the chip center portion is less than is the total area or the total number of the plurality of ohmic regions provided in the chip outer peripheral portion.

5. The semiconductor device according to claim 2, wherein
the plurality of high-resistance junction regions each are provided in the active region, between each of the plurality of ohmic regions and a corresponding one of the plurality of Schottky regions that are adjacent to each other, and
a width of each of the plurality of high-resistance junction regions is in a range of 0.1 μm to 5.0 μm.

6. The semiconductor device according to claim 3, wherein, in the case where the first-conductivity-type region is in the low concentration condition, in the chip center portion of the active region, a percentage of a total area of the plurality of high-resistance junction regions relative to a total area of the plurality of second-conductivity-type regions is 35% or more.

7. The semiconductor device according to claim 3, wherein, in the case where the first-conductivity-type region is in the low concentration condition, in the chip center portion, a percentage of a total area of the plurality of high-resistance junction regions relative to an area of the active region is in a range of 15% to 40%.

8. The semiconductor device according to claim 3, wherein, in the case where the first-conductivity-type region is in the high concentration condition, in the chip outer peripheral portion of the active region, a percentage of a total area of the plurality of high-resistance junction regions relative to a total area of the plurality of second-conductivity-type regions is 35% or more.

9. The semiconductor device according to claim 3, wherein, in the case where the first-conductivity-type region is in the high concentration condition, in the chip outer peripheral portion of the active region, a percentage of a total area of the plurality of high-resistance junction regions relative to an area of the active region is in a range of 15% to 40%.

10. The semiconductor device according to claim 1, wherein the plurality of silicide films contains nickel, silicon, and aluminum.

11. A semiconductor device, comprising:
a semiconductor substrate having an active region and a termination region surrounding a periphery of the active region, the semiconductor substrate having a first main surface and a second main surface opposite to each other;
a first-conductivity-type region provided in the semiconductor substrate and exposed at the first main surface of the semiconductor substrate;
a plurality of second-conductivity-type regions each selectively provided in the first-conductivity-type region, at the first main surface of the semiconductor substrate in the active region; and
a plurality of silicide films each in ohmic contact with a portion of a corresponding one of the plurality of second-conductivity-type regions, wherein
the active region has a chip center portion provided at a center thereof, and a chip outer peripheral portion surrounding a periphery of the chip center portion,
in a case where the first-conductivity-type region is in a low concentration condition where a doping concentration of the first-conductivity-type region is 1.0×10¹⁵/cm³ or more but less than 1.0×10¹⁶/cm³, at least one of the plurality of silicide films provided in the chip outer peripheral portion has a first contact resistance that is in a range of 5×10⁻⁴ Ω/cm² to 5×10⁻³ Ω/cm² and at least another one of the plurality of silicide films provided in the chip center portion has a second contact resistance that is 5×10⁻⁵ Ω/cm² or more but less than 5×10⁻⁴ Ω/cm², and
in a case where the first-conductivity-type region is in a low concentration condition in which the doping concentration of the first-conductivity-type region is in a range of 1.0×10¹⁶/cm³ to 9.0×10¹⁶/cm³, the at least one of the plurality of silicide films provided in the chip outer peripheral portion has the second contact resistance and the at least the another one of the plurality of silicide films provided in the chip center portion has the first contact resistance.

12. A method of manufacturing a semiconductor device including a semiconductor substrate having an active region and a termination region surrounding a periphery of the active region, the method comprising:
forming a first-conductivity-type region in the semiconductor substrate, the first-conductivity-type region constituting a first main surface of the semiconductor substrate;
selectively forming, in the first-conductivity-type region in the active region, at the first main surface of the semiconductor substrate, a plurality of first second-conductivity-type regions;
forming, in the first-conductivity-type region in the termination region, at the first main surface of the semiconductor substrate, a second second-conductivity-type region surrounding the active region;
forming an oxide film at the first main surface of the semiconductor substrate, the oxide film covering the first-conductivity-type region and the plurality of first second-conductivity-type regions;
selectively removing the oxide film and thereby forming, in the oxide film, a plurality of first openings exposing the plurality of first second-conductivity-type regions;
forming a metal material film in the plurality of first openings of the oxide film, the metal material film being in contact with the first main surface of the semiconductor substrate and having, sequentially stacked, a nickel film, an aluminum film, and a metal film with a melting point higher than a melting point of aluminum;
performing a first heat treatment for causing the metal material film and the semiconductor substrate to react, thereby generating a compound layer at the first main surface of the semiconductor substrate, in the plurality of first openings of the oxide film by a self-alignment using the oxide film as a mask;
removing an excess portion of the metal material film after the performing the first heat treatment, the excess portion excluding the compound layer;
performing a second heat treatment at a temperature higher than a temperature of the first heat treatment, thereby generating a nickel silicide in the compound layer and forming a plurality of silicide films in ohmic contact with the semiconductor substrate, the second heat treatment being performed after the removing the excess portion of the metal material film;
after forming the plurality of silicide films, removing portions of the oxide film between the plurality of silicide films, thereby connecting the plurality of first openings and forming a contact hole;
forming a first electrode by sequentially stacking, on the first main surface of the semiconductor substrate, in the contact hole, a titanium film that is in contact with the first-conductivity-type region and forms a plurality of Schottky junctions with the first-conductivity-type region, and a metal electrode film that contains aluminum; and
forming a second electrode at a second main surface of the semiconductor substrate, wherein
the performing the first heat treatment includes:
in a case where the forming of the first-conductivity-type region is in a low concentration condition in which a doping concentration of the first-conductivity-type region is 1.0×10¹⁵/cm³ or more but less than 1.0×10¹⁶/cm³, setting the temperature of the first heat treatment to be 800 degrees C. or higher but less than 1000 degrees C., thereby forming at least one of the plurality of silicide films in a chip outer peripheral portion of the active region that surrounds a periphery of a chip center portion at a center of the active region to have a first contact resistance in a range of 5×10⁻⁴ Ω/cm² to 5×10⁻³ Ω/cm² and setting the temperature of the first heat treatment to be in a range of 1000 degrees C. to 1200 degrees C., thereby forming at least another one of the plurality of silicide films in the chip center portion of the active region to have a second contact resistance of 5×10⁻⁵ Ω/cm² or more but less than 5×10⁻⁴ Ω/cm², and
in a case where the forming of the first-conductivity-type region is in a high concentration condition in which the doping concentration of the first-conductivity-type region is in a range of 1.0×10¹⁶/cm³ to 9.0×10¹⁶/cm³, setting the temperature of the first heat treatment to be in the range of 1000 degrees C. to 1200 degrees C., thereby forming the at least one of the plurality of silicide films in the chip outer peripheral portion of the active region to have the second contact resistance, and setting the temperature of the first heat treatment to be 800 degrees C. or higher but less than 1000 degrees C., thereby forming the at least another one of the plurality of silicide films in the chip center portion of the active region to have the first contact resistance.
